(19) United States
(12) Patent Application Publication
(10) Pub. No.: US 2017/0338084 A1
(43) Pub. Date: Nov. 23, 2017

(54) PLASMA PROCESSING METHOD

(71) Applicant: Tokyo Electron Limited, Tokyo (JP)

(72) Inventor: Takashi NISHIJIMA, Miyagi (JP)

(21) Appl. No.: 15/598,463

(22) Filed: May 18, 2017

(30) Foreign Application Priority Data
May 23, 2016 (JP) 2016-102794

(51) Int. Cl. H01J 37/32

(52) U.S. Cl. CPC H01J 37/32935; H01J 37/32568; H01J 37/32642; H01J 37/32091; H01J 37/3244; H01J 37/32183; H01J 2237/3347

(57) ABSTRACT

A plasma processing method is implemented by a plasma processing apparatus including a processing chamber, a lower electrode, a focus ring arranged around the lower electrode, an inner upper electrode arranged to face the lower electrode, an outer upper electrode electrically insulated from the inner upper electrode, a quartz member arranged between the inner and outer upper electrodes and above the focus ring, a gas supply unit for supplying gas to the processing chamber, a first high frequency power supply unit for applying a first high frequency power for plasma generation to the lower electrode or the inner and outer upper electrodes, a first direct current power supply unit for applying a variable first direct current voltage to the outer upper electrode, and a control unit. The method includes the control unit controlling the variable first direct current voltage to reduce an amount of change in a tilt angle.

### CROSS-REFERENCE TO RELATED APPLICATION

The present application is based on and claims the benefit of priority to Japanese Patent Application No. 2016-102794 filed on May 23, 2016, the entire contents of which are hereby incorporated by reference.

### BACKGROUND OF THE INVENTION

### 1. Field of the Invention

The present invention relates to a plasma processing method.

### 2. Description of the Related Art

It is important for a plasma processing apparatus to be able to generate a uniform plasma and implement a uniform process. In this respect, for example, a technique is known for implementing a uniform process in a parallel plate type plasma processing apparatus by dividing an upper electrode into an inner zone and an outer zone, and applying a direct voltage to each of these zones to control plasma densities in these zones (see e.g., Japanese Unexamined Patent Application Publication No. 2009-239012)

However, even when the plasma density is controlled, phenomena such as tilting can cause non-uniformity of a process performed by a plasma processing apparatus, for example. Tilting is a phenomenon that may occur when etching a target film in a plasma processing apparatus in which the etching profile of holes or lines to be etched vertically are tilted. Tilting occurs as a result of a difference in thicknesses of a plasma sheath formed above an outer periphery portion of a substrate to be processed and a plasma sheath (hereinafter referred to as “sheath”) formed above a ring-shaped focus ring arranged around the outer edge of the substrate to be processed which thickness difference is caused by differences in the structures and materials of the outer periphery portion of the substrate to be processed and the focus ring. That is, due to the difference in the sheath thickness, a level difference (tilting portion) is created at an interface of the sheath (interface between the sheath and plasma), and ions are obliquely incident on the tilting portion at the interface such that the verticality of the etching profile of a hole or a line being formed is compromised to thereby result in tilting of the etched hole or line.

Further, the tilting at the interfaces of the sheath above the outer periphery portion of the substrate to be processed and the sheath above the focus ring may change over time due to a temporal change in the focus ring caused by wear, and the incident angle of ions may change as a result to cause variations in the tilting state. When the tilt angle of tilting exceeds an allowable value, the etching profile is degraded and the yield decreases. Thus, the focus ring needs to be replaced before the tilt angle of tilting exceeds the allowable value.

In other words, if the amount of change in the tilt angle is relatively small, the focus ring does not need to be replaced even if a temporal change occurs in the focus ring due to wear, for example. As a result, the life of the focus ring may be extended.

### SUMMARY OF THE INVENTION

An aspect of the present invention is directed to reducing the amount of change in a tilt angle and controlling the tilt angle to be within an allowable range.

According to one embodiment of the present invention, a plasma processing method is provided that is implemented by a plasma processing apparatus including a processing chamber capable of being evacuated, a lower electrode on which a substrate to be processed in the processing chamber is mounted, a focus ring arranged around the lower electrode, an inner upper electrode arranged to face the lower electrode in the processing chamber, an outer upper electrode that is electrically insulated from the inner upper electrode and is arranged at an outer periphery of the inner upper electrode in the processing chamber, a quartz member arranged between the inner upper electrode and the outer upper electrode and above the focus ring, a gas supply unit for supplying a processing gas to a processing space between the lower electrode and the inner and outer upper electrodes, a first high frequency power supply unit for applying a first high frequency power for generating a plasma of the processing gas by high frequency discharge to the lower electrode or the inner and outer upper electrodes, a first direct current power supply unit for applying a variable first direct current voltage to the outer upper electrode, and a control unit for controlling the variable first direct current voltage. The plasma processing method includes a step of the control unit controlling the variable first direct current voltage to reduce an amount of change in a tilt angle.

### BRIEF DESCRIPTION OF THE DRAWINGS

FIG. 1 is a longitudinal cross-sectional view of a plasma processing apparatus according to an embodiment of the present invention;

FIG. 2 is a table showing examples of tilting depending on the presence or absence of a quartz member according to an embodiment of the present invention;

FIG. 3 is a graph showing examples of tilting depending on control of an outer direct current applied to an outer upper electrode according to an embodiment of the present invention;

FIG. 4 is a graph showing example plasma electron density variations depending on control of the outer direct current applied to the outer upper electrode according to an embodiment of the present invention;

FIG. 5 is a graph showing example etch rate variations depending on the outer direct current applied to the outer upper electrode according to an embodiment of the present invention;

FIG. 6 is a flowchart showing an example plasma processing method according to an embodiment of the present invention; and

FIG. 7 is a table associating a process with a corresponding allowable tilt angle according to an embodiment of the present invention.

### DESCRIPTION OF THE PREFERRED EMBODIMENTS

In the following, embodiments of the present invention will be described with reference to the accompanying drawings. Note that in the following descriptions and the drawings, elements having substantially the same configuration and/or function are given the same reference numerals and overlapping descriptions thereof may be omitted.

[Plasma Processing Apparatus]

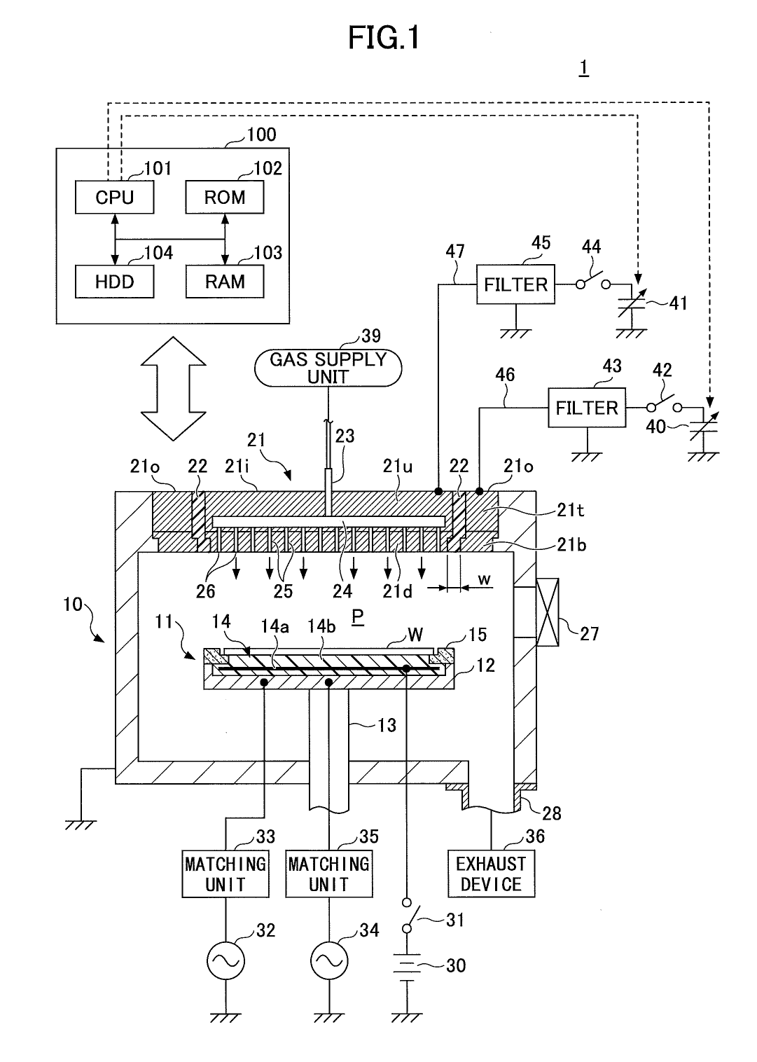

First, an example configuration of a plasma processing apparatus 1 according to an embodiment of the present invention will be described with reference to FIG. 1 showing a longitudinal cross-sectional view of the plasma processing apparatus 1. In the present embodiment, a capacitively coupled plasma processing apparatus is described as an example of the plasma processing apparatus 1. The plasma processing apparatus 1 according to the present embodiment may perform a plasma process, such as an etching process or a film formation process using the CVD (Chemical Vapor Deposition) method, on a semiconductor wafer (hereinafter referred to as “wafer”), for example. Note, however, that the plasma process performed by the plasma processing apparatus 1 according to the present embodiment is not limited to the above example processes.

The plasma processing apparatus 1 includes a processing chamber 10 made of a conductive material such as aluminum. The processing chamber 10 is electrically grounded. A mounting table 11 is disposed inside the processing chamber 10. The mounting table 11 includes a stage 12 that is supported by a support 13, and an electrostatic chuck 14 for electrostatically attracting a wafer W is arranged above the stage 12. The electrostatic chuck 14 includes a chuck electrode 14a that is interposed between insulators 14b. A direct current (DC) power supply 30 is connected to the chuck electrode 14a. When a direct current is supplied from the DC power supply 30 to the chuck electrode 14a, a Coulomb force is generated and the wafer W is electrostatically attracted to the electrostatic chuck 14, and in this way, the wafer W is held by the mounting table 11. An on/off state of the direct current supplied from the DC power supply 30 is controlled by a switch 31.

A ring-shaped focus ring 15 for enhancing in-plane uniformity of etching is disposed at an outer edge portion of the electrostatic chuck 14. The focus ring 15 may be made of silicon (Si), for example.

The mounting table 11 is applied a first high frequency power of 40 MHz, for example, from a first high frequency power supply 32 that is connected to the mounting table 111 via a matching unit 33. The first high frequency power contributes to plasma generation. Also, the mounting table 11 is applied a second high frequency power of 13.56 MHz, for example, from a second high frequency power supply 34 that is connected to the mounting table 11 via a matching unit 35. The second high frequency power contributes to drawing ions from within the plasma onto the wafer W placed on the mounting table 11. With such a configuration, the mounting table 11 also acts as a lower electrode.

The matching unit 33 matches the internal (or output) impedance of the first high frequency power supply 32 and the load impedance. The matching unit 35 matches the internal (or output) impedance of the second high frequency power supply 34 and the load impedance. In this way, while plasma is generated in the processing chamber 10, the matching units 33 and 35 present apparent matching loads between the load impedance and the internal impedance of the first high frequency power supply 32 and the second high frequency power source 34.

A gas shower head 21 for showering gas supplied from a gas supply unit 39 into the processing chamber 10 is arranged on a ceiling of the processing chamber 10. The gas shower head 21 includes a disk-shaped inner upper electrode 21i that faces the mounting table 11 and is arranged parallel to the mounting table 11. The gas shower head 21 includes also includes a ring-shaped outer upper electrode 210 that is concentrically arranged around the outer periphery of the inner upper electrode 21i. The inner upper electrode 21i is positioned above the wafer W and has a diameter that is about the same diameter as the wafer W.

A ring-shaped quartz member 22 may be inserted between the inner upper electrode 21i and the outer upper electrode 21o, for example. The inner upper electrode 21i and the outer upper electrode 210 are electrically insulated from each other by the quartz member 22. The quartz member 22 is arranged above the focus ring 15 and has a width w that is about the same or less than the width of the focus ring 15. The outer upper electrode 210 is arranged outside the focus ring 15.

A diffusion chamber 24 and multiple gas flow paths 25 are formed inside the gas shower head 21. The gas output from the gas supply unit 39 is introduced into the diffusion chamber 24 via a gas introduction port 23. The gas diffused in the diffusion chamber 24 passes through the multiple gas flow paths 25 to be introduced into the processing chamber 10 via multiple gas holes 26. Note that in some embodiments, gas flow paths may similarly be formed in the outer upper electrode 210 as in the inner upper electrode 21i so that gas can also be supplied from the outer upper electrode 21o.

The gas shower head 21 faces the mounting table 11 and is arranged parallel to the mounting table 11. In this way, the gas shower head 21 acts as an upper electrode with respect to the lower electrode of the mounting table 11. The inner upper electrode 21i of the shower head 21 includes an electrode plate 21d directly facing the mounting table 11 and an electrode support 21u detachably arranged above the electrode plate 21d for supporting the electrode plate 21d. The material of the electrode plate 21d is preferably a silicon-containing conductive material, such as Si or SiC, which has little influence on the process being implemented and can maintain good DC application characteristics. The electrode support 21u may be made of alumite-treated aluminum, for example.

Similarly, the outer upper electrode 210 includes an electrode plate 21b that is coplanar with the electrode plate 21d and is arranged around the outer periphery of the electrode plate 21d. The outer upper electrode 210 also includes an electrode support 21t that is detachably arranged above the electrode plate 21b for supporting the electrode plate 21b. The material of the electrode plate 21b and the electrode support 21t may respectively be the same as that of the electrode plate 21d and the electrode support 21u of the inner upper electrode 21i.

A variable DC power supply 40 for outputting a variable first DC voltage (hereinafter also referred to as “outer DC”) to the outer upper electrode 21o and a variable DC power supply 41 for outputting a variable second DC voltage (hereinafter also referred to as “inner DC”) to the inner upper electrode 21i are arranged outside the processing chamber 10.

An output terminal of the variable DC power supply 40 is electrically connected to the outer upper electrode 21o via an on/off switch 42 and a filter circuit 43. The outer DC output from the variable DC power supply 40 is passed through the filter circuit 43 to be applied to the outer upper electrode 21o. On the other hand, the filter circuit 43 prevents a high frequency component from the mounting table 11 that enters a DC supply line 46 via a processing space P and the outer upper electrode 21o from flowing into the variable DC power supply 40 by passing the high frequency wave entering the DC power supply line 46 toward a ground line.

An output terminal of the variable DC power supply 41 is electrically connected to the inner upper electrode 21i via an on/off switch 44 and a filter circuit 45. The inner DC output from the variable DC power supply 41 is passed through the filter circuit 45 to be applied to the inner upper electrode 21i. On the other hand, the filter circuit 45 prevents a high frequency component from the mounting table 11 that enters a DC power supply line 47 via the processing space P and the inner upper electrode 21i from flowing into the variable DC power supply 41 by passing the high frequency component entering the DC power supply line 47 toward a ground line.

Note that the variable DC power supply 40 is an example of a first DC power supply unit that applies a variable first DC voltage to the outer upper electrode 21o. The variable DC power supply 41 is an example of a second DC power supply unit that applies a variable second DC voltage to the inner upper electrode 21i.

An exhaust port 28 is formed in a bottom surface of the processing chamber 10, and an exhaust device 36 is connected to the exhaust port 28 for evacuating gas within the processing chamber 10 to the exterior. In this way, the interior of the processing chamber 10 may be controlled to a predetermined degree of vacuum.

A gate valve 27 is arranged on a side wall of the processing chamber 10. The gate valve 27 opens and closes when loading the wafer W into the processing chamber 10 and unloading the wafer W out of the processing chamber 10.

The plasma processing apparatus 1 includes a control unit 100 for controlling overall operations of the plasma processing apparatus 1. The control unit 100 includes a CPU (Central Processing Unit) 101, a ROM (Read Only Memory) 102, a RAM (Random Access Memory) 103, and a HDD (Hard Disk Drive) 104.

The CPU 101 executes a desired process such as an etching process (described below) based on a recipe stored in the RAM 103 or the HDD 104, for example. The recipe specifies control information for the plasma processing apparatus 1 to execute the desired process including predetermined process conditions, such as the process time, pressure (gas exhaust), high frequency power and voltage, flow rates of various gases, chamber internal temperature (upper electrode temperature, chamber side wall temperature, electrostatic chuck temperature, etc.), for example. Note that such recipe describing process conditions and/or other programs may be stored in a hard disk or a semiconductor memory, for example. The recipe may also be stored in a portable computer-readable storage medium, such as a CD-ROM or a DVD, and set in a predetermined position of a storage area, for example.

When performing an etching process in the plasma processing apparatus 1 having such a configuration, first, the wafer W that is held on a transfer arm is loaded into the processing chamber 10 via the gate valve 27 that is opened. The gate valve 27 is closed after loading the wafer W. The pressure inside the processing chamber 10 is reduced by the exhaust device 36 so that the interior of the processing chamber 10 is brought into a predetermined degree of vacuum.

The wafer W is held above the electrostatic chuck 14 by a pusher pin and is placed on the electrostatic chuck 14 as the pusher pin is lowered. A desired current is supplied from the DC power supply 30 to a chuck electrode 14a of the electrostatic chuck 14, and in this way, the wafer W is electrostatically attracted to the electrostatic chuck 14.

Also, a desired processing gas (etching gas) is introduced into the processing chamber 10 from the gas shower head 21, and high frequency power of each corresponding frequency is applied from the high frequency power supplies 32 and 34 to the mounting table 11. Further, the outer DC is applied to the outer upper electrode 210 from the variable DC power supply 40, and the inner DC from the variable DC power supply 41 is applied to the inner upper electrode 21i.

The etching gas that has been introduced into the processing chamber 10 is dissociated and ionized by high frequency electric power, and a plasma of the etching gas is generated as a result. In this way, a desired plasma process (plasma etching process) may be performed on the wafer W by the action of the generated plasma. After completion of the plasma etching process, the wafer W is held on the transfer arm and unloaded from the processing chamber 10 via the gate valve 27 that is opened.

[Quartz Member Arranged Above Focus Ring]

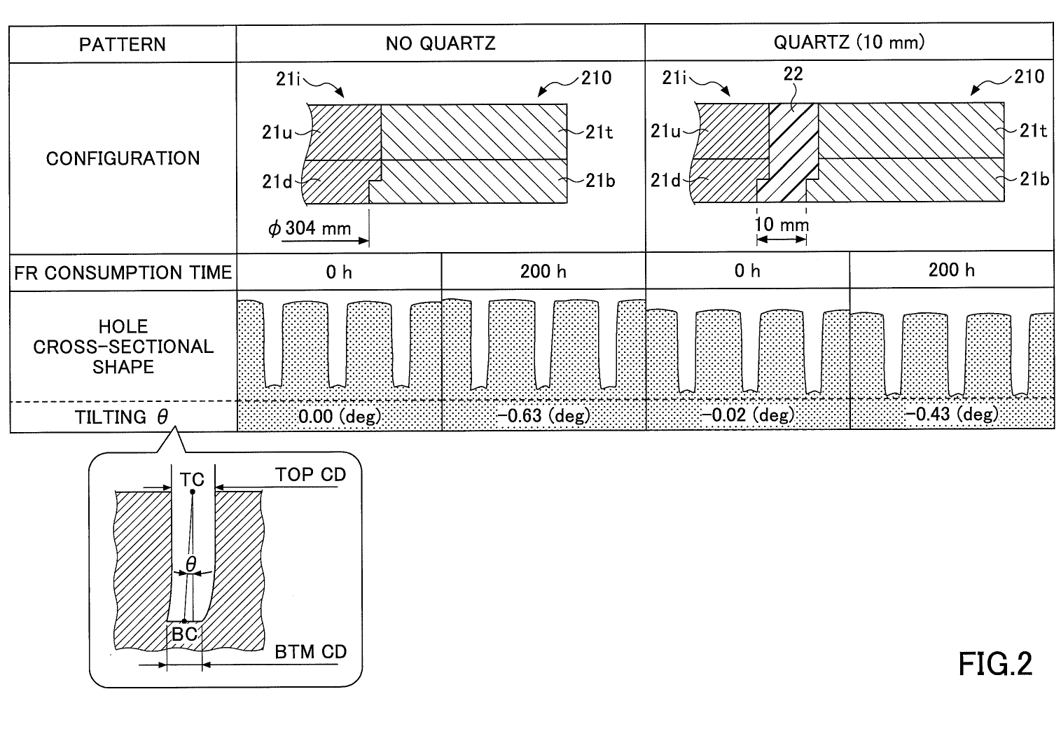

In the plasma processing apparatus 1 according to the present embodiment, the quartz member 22 is arranged above the focus ring 15. FIG. 2 shows example experimental results of tilting depending on the presence/absence of the quartz member 22. The right side of FIG. 2 shows an example of tilting that occurred with the consumption of the focus ring 15 having the configuration according to the present embodiment including the quartz member 22 with a width w equal to 10 mm arranged between the inner upper electrode 21i and the outer upper electrode 21o. The left side of FIG. 2 shows an example of tilting that occurred with the consumption of the focus ring 15 having a configuration according to a comparative example in which no quartz member 22 is arranged between the inner upper electrode 21i and the outer upper electrode 21o.

As process conditions of the present experiment, a first high frequency power with a frequency of 40 MHz and a second high frequency power with a frequency of 3.2 MHz were applied to the lower electrode, a fluorine-containing gas was supplied to generate a plasma, and the generated plasma was used to etch a silicon oxide (SiO₂) film. Further, an outer DC of 500 V was applied to the outer upper electrode 21o and an inner DC of 500 V was applied to the inner upper electrode 21i.

Note that in FIG. 2, a tilt angle θ is defined as an angle formed between a line extending in a vertical direction of a hole formed in the wafer W and a line passing through a top center point TC of a top diameter of a cross-sectional opening of the hole (TOP CD) and a bottom center point BC of a bottom diameter of a bottom section of the hole (BTM CD). When the tilt angle θ is a negative value, this means that the etching profile is tilted inward with respect to the vertical direction. When the tilt angle θ is a positive value, this means that the etching profile it tilted outward with respect to the vertical direction.

As can be appreciated from the right side of FIG. 2, when an etching process was performed under the above-described process conditions in the plasma processing apparatus 1 according to the present embodiment including the quartz member 22, the tilt angle θ was −0.02 (deg) when the consumption time of the focus ring 15 (FR consumption time) was 0 h (new focus ring 15). Also, the tilt angle θ was −0.43 (deg) when the FR consumption time was 200 h.

On the other hand, as can be appreciated from the left side of FIG. 2, when an etching process was performed under the above-described process conditions in the plasma processing apparatus 1 according to the comparative example without the quartz member 22, the tilt angle θ was 0.00 (deg) when the FR consumption time was 0 h, and the tilt angle θ was −0.63 (deg) when the FR consumption time was 200 h. Note that in the present experiment, the tilt angle θ of a hole formed in an outer peripheral portion of the wafer W at a radius of about 150 mm was measured.

As can be appreciated from the above, by using the plasma processing apparatus 1 having the configuration according to the present embodiment including the quartz member 22 arranged above the focus ring 15, as the focus ring 15 is consumed, the tilt angle θ can be controlled to be at a smaller angle as compared with the case of using the plasma processing apparatus 1 having the configuration according to the comparative example in which no quartz member 22 is provided. That is, in the plasma processing apparatus 1 having the configuration according to the present embodiment including the quartz member 22 arranged above the focus ring 15, the verticality of the etching profile of a hole formed in the wafer W may be more easily maintained.

As can be appreciated from the above, by arranging the quartz member 22 above the focus ring 15 in the plasma processing apparatus 1 according to the present embodiment, the amount of change in the tilt angle can be reduced. In this way, the replacement timing of the focus ring 15 can be delayed, for example. That is, by arranging the quartz member 22 above the focus ring 15 in the plasma processing apparatus 1 according to the present embodiment, the life of the focus ring 15 can be prolonged, for example.

[Control of Outer DC]

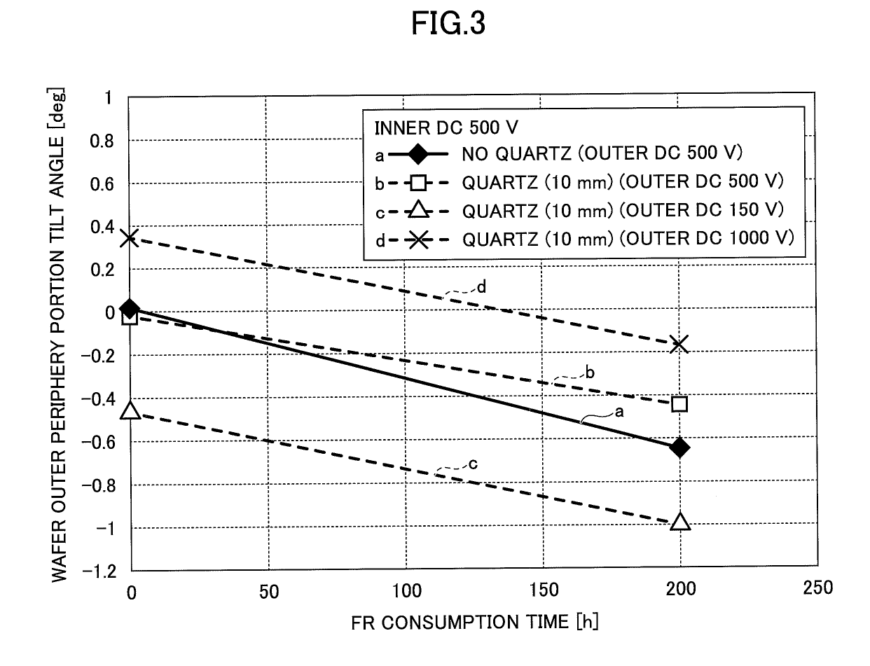

In the following, tilting when the outer DC is variably controlled will be described. FIG. 3 is a graph showing example experimental results of tilting (tilt angles θ) when the outer DC applied to the outer upper electrode 210 was controlled to 150 V, 500 V, and 1000 V. Note that in the present experiment, the outer DC was variably controlled, but the inner DC applied to the inner upper electrode 21i was fixed at 500 V.

In the graph of FIG. 3, the horizontal axis represents the consumption time (h) of the focus ring 15, and the vertical axis represents the tilt angle θ at the outer peripheral portion of the wafer W. Note that in the present experiment, the tilt angle θ (deg) was measured at the peripheral portion (at a radius of about 150 mm) of the wafer W.

In FIG. 3, line a represents a relationship between the consumption time of the focus ring 15 and the tilt angle θ in the case where the plasma processing apparatus 1 according to the comparative example with no quartz member 22 arranged above the focus ring 15 was used to perform etching (outer DC 500 V, inner DC 500 V).

Lines b, c, and d in FIG. 3 represent relationships between the consumption time of the focus ring 15 and the tilt angle θ in the case where the plasma processing apparatus 1 according to the present embodiment including the quartz member 22 having a width w equal to 10 mm arranged above the focus ring 15 was used to perform etching. Specifically, line b represents a case where the outer DC was controlled to 500 V and the inner DC was controlled to 500 V. Line c represents a case where the outer DC was controlled to 150 V and the inner DC was controlled to 500 V. Line d represents a case where the outer DC was controlled to 1000 V and the inner DC was controlled to 500 V.

As can be appreciated from the above, the tilt angle θ can be controlled by variably controlling the outer DC. Also, the amount of change in the tilt angle θ can be controlled by variably controlling the outer DC. That is, provided the inner DC is controlled to a fixed voltage value, the tilt angle θ tends to become smaller as the voltage of outer DC is increased. That is, by controlling the outer DC, even when the focus ring 15 is consumed, variations in the tilt angle θ can be reduced.

Thus, taking into account the fact that different processes may have different allowable tilt angles, the control unit 100 may vary a setting value for the outer DC for each process in view of the corresponding allowable tilt angle. By controlling the tilt angle to be within a corresponding allowable range for each process to be executed, the replacement timing of the focus ring 15 can be extended and the life of the focus ring 15 can be prolonged, for example.

[Process Control Based on Outer DC]

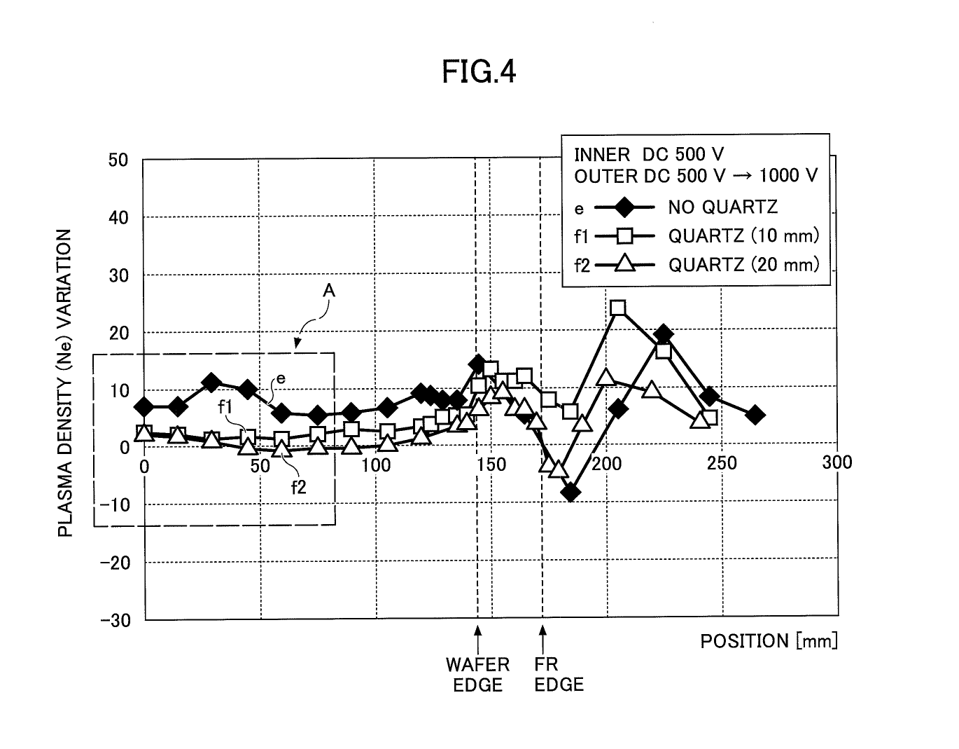

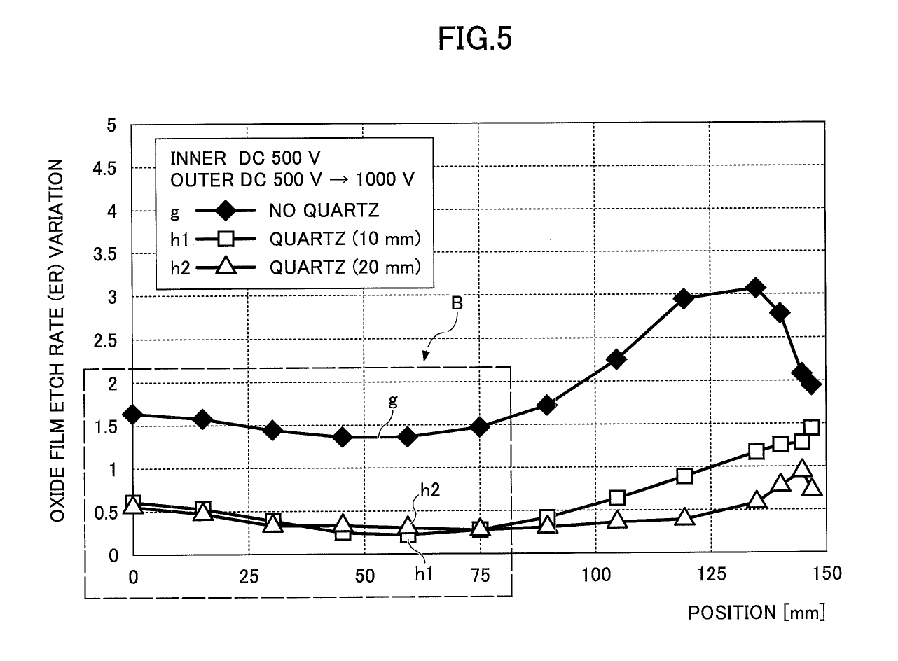

In the following, process control by controlling the outer DC will be described with reference to FIGS. 4 and 5 that represent example experimental results of controlling the outer DC applied to the outer upper electrode 21o. FIG. 4 is a graph showing plasma electron density (Ne) variations resulting from controlling the outer DC applied to the outer upper electrode 21o. FIG. 5 is a graph showing etching rate (ER) variations resulting from controlling the outer DC applied to the outer upper electrode 21o.

As process conditions of the experiments of FIGS. 4 and 5, a first high frequency power with a frequency of 40 MHz and a second high frequency power with a frequency of 3.2 MHz were applied to the lower electrode, a fluorine-containing gas was supplied to generate a plasma, and the generated plasma was used to etch a silicon oxide. Also, after applying the outer DC of 500 V to the outer upper electrode 210 and applying the inner DC of 500 V to the inner upper electrode 21i, the outer DC was changed from 500 V to 1000 V while maintaining the inner DC to the fixed voltage of 500 V.

In the graph of FIG. 4, the horizontal axis represents a position in the radial direction of the wafer W, and the vertical axis represents the plasma electron density (Ne) variation. The wafer W was placed over a region extending from a radial position of 0 mm (center) to a radial position of 150 mm. The outer peripheral portion of the wafer W was arranged around the radial position of 150 mm. The ring-shaped focus ring 15 was arranged at a radial position of 150 mm to 175 mm from the center 0 mm. In FIG. 4, lines f1 and f2 represent plasma electron density (Ne) variations when the quartz member 22 was arranged above the focus ring 15 according to the present embodiment, and line e represents the plasma electron density (Ne) variation when no quartz member 22 was arranged according to the comparative example. As can be appreciated from FIG. 4, when the outer DC was raised (from 500 V to 1000 V), variations in the plasma electron density (Ne) could be reduced and uniformity of the plasma electron density (Ne) could be maintained at a center side of the wafer W (particularly in region A of FIG. 4). That is, by providing the quartz member 22 above the focus ring 15, when the outer DC is raised, variations in the plasma electron density (Ne) at the center side of the wafer W can be reduced, and the plasma electron density (Ne) at the outer peripheral portion of the wafer W can be desirably controlled.

Note that controllability of the plasma electron density (Ne) was substantially the same both in the case where the quartz member 22 had a width w of 10 mm and the case where the quartz member 22 had a width w of 20 mm.

In the graph of FIG. 5, the horizontal axis represents the position in the radial direction of the wafer W, and the vertical axis represents a variation in the etch rate (ER) of the silicon oxide film. In FIG. 5, lines h1 and h2 represent etch rate (ER) variations when the quartz member 22 is arranged above the focus ring 15 according to the present embodiment, and line g represents the etch rate (ER) variation when no quartz member 22 is provided according to the comparative example. As can be appreciated from FIG. 5, when the outer DC was raised, variations in the etch rate (ER) could be reduced and uniformity of the etch rate (ER) could be maintained at the center side of the wafer W (particularly in region B of FIG. 5). That is, by providing the quartz member 22 above the focus ring 15, when the outer DC is raised, variations in the etch rate (ER) at the center side of the wafer W can be reduced, and the etch rate (ER) at the outer side of the outer peripheral portion of the wafer W can be desirably controlled.

Note that controllability of the etch rate (ER) was substantially the same both in the case where the width w of the quartz member 22 was 10 mm and the case where the width w of the quartz member 22 was 20 mm.

In the above experiment, the inner DC applied to the inner upper electrode 21i was controlled to 500 V. By applying the inner DC to the inner upper electrode 21i as described above, when the outer DC is applied to the outer upper electrode 21o, influences on the etch rate (ER) and the plasma electron density (Ne) at the center side of the wafer W can be reduced, for example.

[Plasma Processing Method]

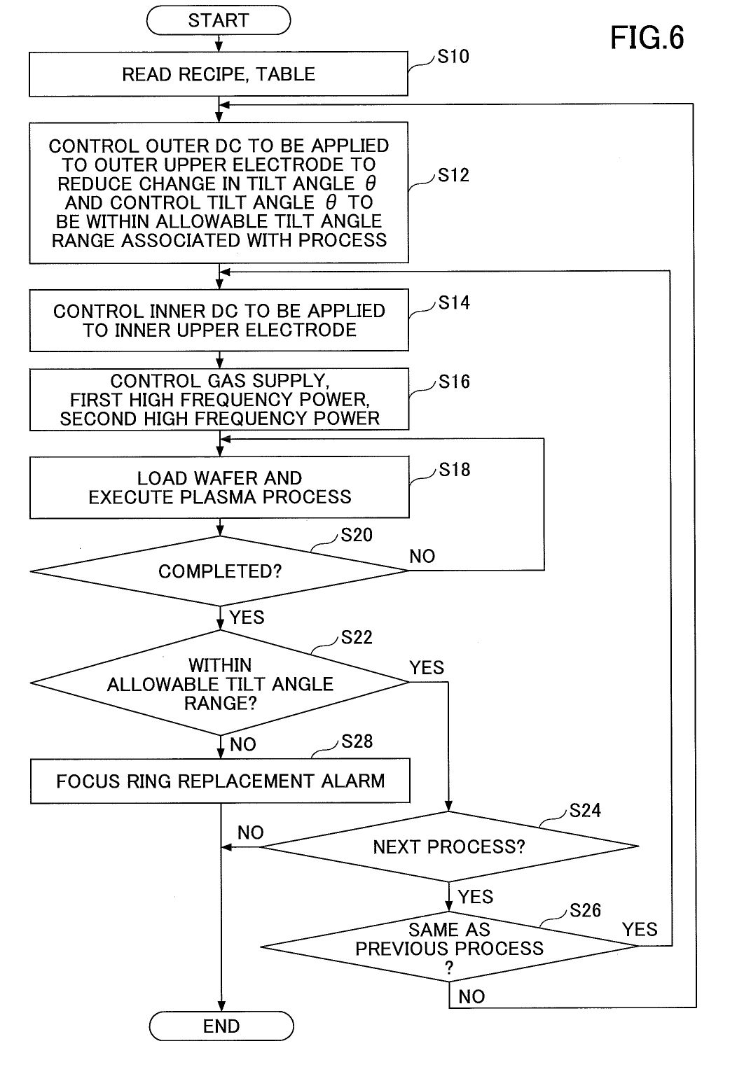

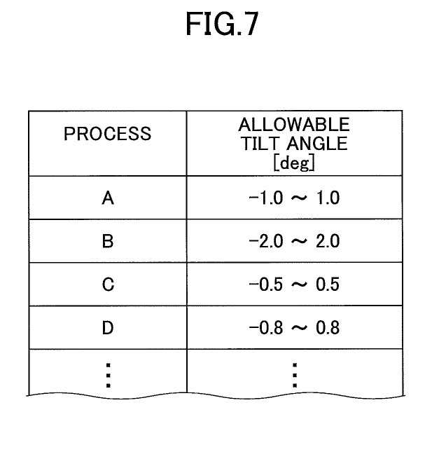

In the following, a plasma process method implemented by the plasma processing apparatus 1 according to the present embodiment will be described with reference to FIGS. 6 and 7. FIG. 6 is a flowchart showing an example plasma processing method according to the present embodiment. FIG. 7 shows an example table associating a process with a corresponding allowable tilt angle according to the present embodiment.

The plasma processing method described below is executed by the CPU 101 of the control unit 100. The table of FIG. 7 may be stored in a storage unit, such as the RAM 103 or the HDD 104 of the control unit 100, for example, and is referred to by the CPU 101 when the CPU 101 executes the plasma processing method.

When the process of FIG. 6 is started, the control unit 100 reads a corresponding recipe and the table stored in the RAM 103 or the HDD 104 (step S10). In this way, the control unit 100 determines a process to be executed and the corresponding allowable tilt angle for the process.

Then, the control unit 100 controls the outer DC applied to the outer upper electrode 210 to control the amount of change in the tilt angle θ to be within the allowable tilt angle range for the process to be executed (step S12). As described above with reference to FIG. 3, the control unit 100 preferably controls the outer DC applied to the outer upper electrode 210 to increase in voltage as the allowable tilt angle becomes smaller.

Then, the control unit 100 controls the inner DC applied to the inner upper electrode 21i (step S14). In the present embodiment, the control unit 100 controls the inner DC to a fixed voltage. Note, however, that the inner DC may also be variably controlled. Then, the control unit 100 controls the supply of gas, the first high frequency power, and the second high frequency power (step S16).

Then, the control unit 100 loads the wafer W and executes the process (step S18). For example, in the present embodiment, a plasma etching process is performed. Then, the control unit 100 determines whether the process has been completed (step S20). If it is determined that the process has been completed, the control unit 100 proceeds to step S22.

In step S22, the control unit 100 determines whether the tilt angle e is within the allowable tilt angle range. If the control unit 100 determines that the tilt angle e is outside the allowable tilt angle range, the control unit 100 outputs an alarm prompting replacement of the focus ring 15, and ends the present process.

On the other hand, if the control unit 100 determines in step S22 that the tilt angle e is within the allowable tilt angle range, the control unit 100 determines whether there is a next process to be executed (step S24). Upon determining that there is no next process, the control unit 100 ends the present process. On the other hand, if the control unit 100 determines that there is a next process to be executed, the control unit 100 determines whether the next process is the same as the previously executed process (step S26). If the control unit 100 determines that the next process is the same as the previously executed process, the process returns to step S14, and the control unit 100 repeats the processes from step S14 and onward to execute the next process.

On the other hand, if the control unit 100 determines in step S26 that the next process is not the same as the previously executed process, the control unit 100 returns to step S12. The control unit 100 refers to the table and controls the outer DC applied to the outer upper electrode 210 to control the amount of change in the tilt angle θ to be within the corresponding allowable tilt angle range for the next process to be executed (step S12). Then, the control unit 100 repeats the processes from step S14 and onward to execute the next process.

As described above, in the plasma processing method according to the present embodiment, the control unit 100 uses the plasma processing apparatus 1 according to the present embodiment including the quartz member 22 arranged above the focus ring 15 and controls the outer DC to control the amount of change in the tilt angle θ. In this way, even if the focus ring 15 changes over time due to consumption, for example, the life of the focus ring 15 can be prolonged by reducing the amount of change in the tilt angle θ.

Also, by arranging the quartz member 22 above the focus ring 15, variations in the plasma electron density (Ne) and the etch rate (ER) at the center side of the wafer W can be suppressed by controlling of the outer DC. Also, by controlling the inner DC, variations in the etch rate (ER) and the plasma electron density (Ne) distribution at the center side of the wafer W can be further be suppressed.

That is, in the plasma processing method using the plasma processing apparatus 1 according to the present embodiment, by primarily controlling the outer DC, plasma uniformity and stability in the etch rate may be achieved at the center side of the wafer W while improving controllability of the plasma electron density and the etch rate at the outer peripheral side of the wafer W. Further, by controlling the outer DC to reduce the amount of change in the tilt angle θ, the verticality of the etching profile may be improved, the replacement timing of the focus ring 15 may be delayed, and the life of the focus ring 15 may be prolonged, for example.

Although a plasma processing method according to the present invention has been described above with respect to illustrative embodiments, the present invention is not limited to the above embodiments and various modifications and changes may be made within the scope of the present invention. Also, note that features of the above-described embodiments can be combined to the extent practicable.

For example, the plasma processing method according to the present invention can be applied not only to a capacitively coupled plasma (CCP) processing apparatus but also to other plasma processing apparatuses. Examples of other plasma processing apparatuses include an inductively coupled plasma (ICP) processing apparatus, a plasma processing apparatus using a radial line slot antenna, a helicon wave plasma (HWP) processing apparatus, an electron cyclotron resonance (ECR) plasma processing apparatus, and the like.

Also, although the wafer W is described above as a substrate to be processed (etched), the present invention is not limited thereto, and various substrates may be subjected to the plasma processing method according to the present invention, such as a substrate used in an LCD (Liquid Crystal Display) or an FPD (Flat Panel Display), a photomask, a CD substrate, or a printed circuit board, for example.

What is claimed is

1. A plasma processing method implemented by a plasma processing apparatus including
a processing chamber capable of being evacuated;
a lower electrode on which a substrate to be processed in the processing chamber is mounted;
a focus ring arranged around the lower electrode;
an inner upper electrode arranged to face the lower electrode in the processing chamber;
an outer upper electrode that is electrically insulated from the inner upper electrode and is arranged at an outer periphery of the inner upper electrode in the processing chamber;
a quartz member arranged between the inner upper electrode and the outer. upper electrode and above the focus ring;
a gas supply unit for supplying a processing gas to a processing space between the lower electrode and the inner and outer upper electrodes;
a first high frequency power supply unit for applying to the lower electrode or the inner and outer upper electrodes, a first high frequency power for generating a plasma of the processing gas by high frequency discharge;
a first direct current power supply unit for applying a variable first direct current voltage to the outer upper electrode; and
a control unit for controlling the variable first direct current voltage;
the plasma processing method comprising a step of the control unit controlling the variable first direct current voltage to reduce an amount of change in a tilt angle.

2. The plasma processing method according to claim 1, wherein
the tilt angle is an angle formed between a line extending in a vertical direction of a hole formed in the substrate and a line passing through a top center point of a top diameter of a cross-sectional opening of the hole and a bottom center point of a bottom diameter of a bottom section of the hole.

3. The plasma processing method according to claim 1,
wherein the plasma processing apparatus further includes a second direct current power supply unit for applying a variable second direct current voltage to the inner upper electrode; and
wherein the plasma processing method comprises a step of controlling the variable second direct current voltage applied to the inner upper electrode.

4. The plasma processing method according to claim 1, wherein
the control unit refers to a storage unit that associates a process to be executed with an allowable tilt angle and controls the variable first direct current voltage to reduce the amount of change in the tilt angle and control the tilt angle to be within the allowable tilt angle associated with the process to be executed.
